(19) United States
(12) Patent Application Publication
(10) Pub. No.: US 2021/0255251 A1
(43) Pub. Date: Aug. 19, 2021

(54) ACTION GENERATOR, ENERGY STORAGE DEVICE EVALUATOR, COMPUTER PROGRAM, LEARNING METHOD, AND EVALUATION METHOD

(71) Applicant: GS Yuasa International Ltd., Kyoto-shi, Kyoto (JP)

(72) Inventor: Nan UKUMORI, Kyoto-shi, Kyoto (JP)

(21) Appl. No.: 16/973,388

(22) PCT Filed: Jun. 12, 2019
(86) PCT No.: PCT/JP2019/023315

§ 371 Date: Dec. 8, 2020

(30) Foreign Application Priority Data
Jun. 13, 2018 (JP) 2018-112966

(51) Int. Cl. G01R 31/392; H02J 7/00

(52) U.S. Cl. CPC G01R 31/392; H02J 7/00041; H02J 7/0048; H02J 7/005

(57) ABSTRACT

An action generator includes: an action selection unit that selects an action including setting related to a state of charge (SOC) of an energy storage device on the basis of action evaluation information; a state acquisition unit that acquires a state including a state of health (SOH) of the energy storage device when the action selected by the action selection unit is executed; a reward acquisition unit that acquires a reward in reinforcement learning when the action selected by the action selection unit is executed; an updating unit that updates the action evaluation information on the basis of the state acquired by the state acquisition unit and the reward acquired by the reward acquisition unit; and an action generation unit that generates an action corresponding to the state of the energy storage device on the basis of the action evaluation information updated by the updating unit.

### CROSS REFERENCE TO RELATED APPLICATIONS

This application is a national stage application, filed under 35 U.S.C. § 371, of International Application No. PCT/JP2019/023315, filed Jun. 12, 2019, which international application claims priority to and the benefit of Japanese Application No. 2018-112966, filed Jun. 13, 2018; the contents of both of which as are hereby incorporated by reference in their entireties.

### BACKGROUND

### Technical Field

The present invention relates to an action generator, an energy storage device evaluator, a computer program, a learning method, and an evaluation method.

### Description of Related Art

An energy storage device has been widely used in an uninterruptible power supply, a d.c. or a.c. power supply included in a stabilized power supply, and the like. In addition, the use of energy storage devices in large-scale power systems that store renewable energy or electric power generated by existing power generating systems is expanding.

In such a power system, market transactions are conducted in which electric power generated by a photovoltaic power generator, a wind power generator, or the like is sold to an electric power company. Patent Document JP-A-2017-151756 discloses a technique for providing timing at which electric power can be sold at a higher price on the basis of a predicted amount of electric power demand and an amount of electric power that can be supplied.

### BRIEF SUMMARY

However, the technique of Patent Document JP-A-2017-151756 does not consider the health of the energy storage device. For example, when the system is operated with priority given only to the timing for selling electric power, there is a possibility that the health of the energy storage device is lowered. On the other hand, when the health of the energy storage device is given excessive priority, it does not lead to an increase in the amount of electric power sold or a reduction in electric power purchase.

An object of the present invention is to provide an action generator, an energy storage device evaluator, a computer program, a learning method, and an evaluation method which can achieve the optimum operation of the entire system in consideration of the health of an energy storage device.

An action generator includes: an action selection unit that selects an action including setting related to a state of charge (SOC) of an energy storage device on the basis of action evaluation information; a state acquisition unit that acquires a state including a state of health (SOH) of the energy storage device when the action selected by the action selection unit is executed; a reward acquisition unit that acquires a reward when the action selected by the action selection unit is executed; an updating unit that updates the action evaluation information on the basis of the state acquired by the state acquisition unit and the reward acquired by the reward acquisition unit; and an action generation unit that generates an action corresponding to the state of the energy storage device on the basis of the action evaluation information updated by the updating unit.

A computer program causes a computer to execute processing of: selecting an action that includes setting related to SOC of an energy storage device on the basis of action evaluation information; acquiring a state that includes a reward and a state of health (SOH) of the energy storage device when the selected action is executed; and updating the action evaluation information such that the acquired reward increases, to have an action corresponding to the state of the energy storage device learned.

A learning method includes: selecting an action that includes setting related to SOC of an energy storage device on the basis of action evaluation information; acquiring a state that includes a reward and a state of health (SOH) of the energy storage device when the selected action is executed; and updating the action evaluation information such that the acquired reward increases, to have an action corresponding to the state of the energy storage device learned.

An energy storage device evaluator includes: a learned model that includes updated action evaluation information; a state acquisition unit that acquires a state including SOH of an energy storage device; and an evaluation generation unit that inputs the state acquired by the state acquisition unit to the learned model and generates an evaluation result of the energy storage device on the basis of an action that includes setting related to SOC of the energy storage device output by the learned model.

A computer program causes a computer to execute the processing of: acquiring a state that includes a state of health (SOH) of a storage device; inputting the acquired state into a learned model that includes updated action evaluation information; and generating an evaluation result of the energy storage device on the basis of an action that includes setting related to SOC of the energy storage device output by the learned model.

An evaluation method includes: acquiring a state that includes a state of health (SOH) of a storage device; inputting the acquired state into a learned model that includes updated action evaluation information; and generating an evaluation result of the energy storage device on the basis of an action that includes setting related to SOC of the energy storage device output by the learned model.

With the above configuration, it is possible to achieve the optimum operation of the entire system in consideration of the health of the energy storage device.

### BRIEF DESCRIPTION OF THE FIGURES

FIG. 1 is a diagram showing an outline of a remote monitoring system.

FIG. 2 is a block diagram showing an example of the configuration of the remote monitoring system.

FIG. 3 is a diagram showing an example of a connection mode of a communication device.

FIG. 4 is a block diagram showing an example of a configuration of a server apparatus.

FIG. 5 is a schematic diagram showing an example of power consumption amount information.

FIG. 6 is a schematic diagram showing an example of power generation amount information.

FIG. 7 is a schematic diagram showing an example of transition of a supply/demand imbalance amount of electric power in each season.

FIG. 8 is a schematic diagram showing an example of ambient temperature information.

FIG. 9 is a schematic diagram showing an operation of a life prediction simulator.

FIG. 10 is a schematic diagram showing an example of a virtual SOC fluctuation.

FIG. 11 is a schematic diagram showing an example of a feature amount of SOC.

FIG. 12 is a schematic diagram showing an example of setting related to SOC in an example of an operation for power selling use.

FIG. 13 is a schematic diagram showing an example of reinforcement learning.

FIG. 14 is a schematic diagram showing an example of a configuration of an evaluation value table.

FIG. 15 is a schematic diagram showing an example of an action.

FIG. 16 is a schematic diagram showing an example of the state transition of reinforcement learning.

FIG. 17 is a schematic diagram showing an example of an operation method obtained by reinforcement learning.

FIG. 18 is a schematic diagram showing an example of transition of SOH according to the operation method obtained by reinforcement learning.

FIG. 19 is a schematic diagram showing an example of setting related to SOC in an example of an operation for self-sufficient use.

FIG. 20 is a schematic diagram showing an example of a configuration of an evaluation value table in a second example.

FIG. 21 is a schematic diagram showing an example of the operation method of the second example obtained by reinforcement learning.

FIG. 22 is a flowchart showing an example of a processing procedure for reinforcement learning.

FIG. 23 is a block diagram showing an example of a configuration of a server apparatus as an energy storage device evaluator.

FIG. 24 is a flowchart showing an example of a processing procedure for a method of evaluation of an energy storage device by the server apparatus.

FIG. 25 is a schematic diagram showing an example of an evaluation result generated by the server apparatus.

### DETAILED DESCRIPTION OF VARIOUS EMBODIMENTS

An action generator includes: an action selection unit that selects an action including setting related to a state of charge (SOC) of an energy storage device on the basis of action evaluation information; a state acquisition unit that acquires a state including a state of health (SOH) of the energy storage device when the action selected by the action selection unit is executed; a reward acquisition unit that acquires a reward when the action selected by the action selection unit is executed; an updating unit that updates the action evaluation information on the basis of the state acquired by the state acquisition unit and the reward acquired by the reward acquisition unit; and an action generation unit that generates an action corresponding to the state of the energy storage device on the basis of the action evaluation information updated by the updating unit.

A computer program causes a computer to execute processing of: selecting an action that includes setting related to SOC of an energy storage device on the basis of action evaluation information; acquiring a state that includes a reward and a state of health (SOH) of the energy storage device when the selected action is executed; and updating the action evaluation information such that the acquired reward increases, to have an action corresponding to the state of the energy storage device learned.

A learning method includes: selecting an action that includes setting related to SOC of an energy storage device on the basis of action evaluation information; acquiring a state that includes a reward and a state of health (SOH) of the energy storage device when the selected action is executed; and updating the action evaluation information such that the acquired reward increases, to have an action corresponding to the state of the energy storage device learned.

The action selection unit that selects an action including the setting related to a state of charge (SOC) of an energy storage device on the basis of action evaluation information. The action evaluation information is an action value function or a table for determining an evaluation value of an action in a given state of the environment in reinforcement learning and means a Q-value or a Q-function in Q-learning. The setting related to SOC includes, for example, setting of an upper limit value of SOC (to avoid overcharge of the energy storage device), a lower limit value of SOC (to avoid overdischarge of the energy storage device), an SOC adjustment amount for setting SOC of the energy storage device to a required value (to charge the energy storage device in advance), and the like. The action selection unit corresponds to an agent in reinforcement learning and can select an action having the highest evaluation in the action evaluation information.

The state acquisition unit acquires a state including a state of health (SOH) of the energy storage device when the selected action is executed. When the action selected by the action selection unit is executed, the state of the environment changes. The state acquisition unit acquires the changed state.

The reward acquisition unit acquires a reward when the selected action is performed. The reward acquisition unit acquires a high value (positive value) when the action selection unit causes a desired result to act on the environment. When the reward is 0, there is no reward, and when the reward is a negative value, there is a penalty.

The updating unit updates the action evaluation information on the basis of the acquired state and reward. More specifically, the updating unit corresponds to the agent in reinforcement learning and updates the action evaluation information in a direction of maximizing the reward for the action. This enables learning of an action that is expected to have the greatest value in a given state of the environment.

The action generation unit generates an action corresponding to a system operation that includes the state of the energy storage device on the basis of the updated action evaluation information. Thus, for various states (e.g., various SOH) of the energy storage device, for example, the optimum value of the setting related to SOC can be obtained by reinforcement learning, so that the optimum operation of the system including the energy storage device can be achieved.

In the action generator, the setting related to SOC may include the setting of at least one of the upper limit value of SOC, the lower limit value of SOC, and the SOC adjustment amount based on charge or discharge to/from the energy storage device.

The setting related to SOC includes the setting of at least one of the upper limit value of SOC, the lower limit value of SOC, and the SOC adjustment amount based on charge or discharge to/from the energy storage device. Note that the setting may include the maximum current and the upper and lower limit voltages of the energy storage device. Setting the upper limit value of SOC can prevent the overcharge of the energy storage device. Setting the lower limit value of SOC can prevent the overdischarge of the energy storage device. Setting the upper limit value and the lower limit value of SOC can adjust the central SOC of SOC and the fluctuation range of SOC which change with the charge and discharge of the energy storage device. The center of SOC is the average of the changing SOC, and the fluctuation range of SOC is the difference between the maximum and minimum values of the changing SOC. The degradation value of the energy storage device changes in accordance with the center of SOC and the fluctuation range of SOC. This makes it possible to learn the setting related to SOC for reducing the degree of degradation in accordance with the state (e.g., SOH) of the energy storage device.

The SOC adjustment amount is an adjustment amount for charging the energy storage device from the power system at night and setting SOC of the energy storage device to a required value before connecting the energy storage device to a load. For example, in a case where SOC of the energy storage device, which has 20% of SOC, is set to 90%, the SOC adjustment amount is 70% (=90−20). Thus, surplus power from day to night can be sold while the power demand of the load is satisfied, and the setting related to SOC for reducing the degree of degradation of the energy storage device can be learned while the power selling is considered. In addition, by using electric power, charged at night when the electricity rate is low, in the daytime, it is possible to learn an operation method for a system that avoids buying electricity during the daytime when the electricity rate is high.

In the action generator, the action may include setting the ambient temperature of the energy storage device.

The action includes setting the ambient temperature of the energy storage device. The temperature of the energy storage device can be estimated on the basis of the ambient temperature of the energy storage device. The degradation value of the energy storage device changes in accordance with the temperature of the energy storage device, so that it is possible to learn the setting of ambient temperature that can reduce the degree of degradation in accordance with the state (e.g., SOH) of the energy storage device. On the other hand, the cost increases due to the consumption of electric power for adjusting the ambient temperature. With the present disclosure, it is possible to learn the setting of the ambient temperature to minimize such power consumption.

The action generator may include: a power generation amount information acquisition unit that acquires power generation amount information in a power generating facility to which the energy storage device is connected; a power consumption amount information acquisition unit that acquires power consumption amount information in a power demand facility; an SOC transition estimation unit that estimates transition of SOC of the energy storage device on the basis of the power generation amount information, the power consumption amount information, and the action selected by the action selection unit; and an SOH estimation unit that estimates SOH of the energy storage device on the basis of the transition of the SOC estimated by the SOC transition estimation unit. The state acquisition unit may acquire SOH estimated by the SOH estimating unit

The power generation amount information acquisition unit acquires power generation amount information in a power generating facility (power system) to which the energy storage device is connected. The power generation amount information is information representing the transition of generated power over a predetermined period. The predetermined period can be set to, for example, one day, one week, one month, spring, summer, autumn, winter, one year, or the like. Here, the power generation amount refers to the amount of electric power generated by renewable energy or an existing power generating system. The power generating system may be an electric power company or a large commercial (civilian) power generating facility, a business office, a building, a public facility such as a commercial facility, a government office, or a railway (station building), or a small power generating facility such as a household generating system.

The power consumption amount information acquisition unit acquires power consumption amount information in a power demand facility (power system). The power consumption amount information is information representing the transition of power consumption over a predetermined period. The predetermined period can be set to the same period as the predetermined period of the power generation amount information. The power consumption amount information is information representing a load pattern requested by a user using the energy storage device. Note that the power system includes the power generating facility and the power demand facility.

The SOC transition estimation unit estimates the transition of SOC of the energy storage device on the basis of the power generation amount information, the power consumption amount information, and the selected action. When the generated power is larger than the power consumption in the predetermined period, the energy storage device is charged, and SOC increases. On the other hand, when the generated power is smaller than the power consumption, the energy storage device is discharged, and SOC decreases. In the predetermined period, the charge and discharge of the energy storage device may not be performed (e.g., at night.). The fluctuation of SOC is limited by the upper limit value and the lower limit value. With the SOC adjustment amount, SOC can be increased. Thereby, the transition of SOC can be estimated over the predetermined period.

The SOH estimation unit estimates SOH of the energy storage device on the basis of the estimated SOC transition. The state acquisition unit acquires SOH estimated by the SOH estimation unit. A degradation value Qdeg of the energy storage device after the predetermined period can be expressed by the sum of an energization degradation value Qcur and a non-energization degradation value Qcnd. When the elapsed time is represented by t, the non-energization degradation value Qcnd can be obtained by, for example, Qcnd=K1×√(t). The coefficient K1 is a function of SOC. The energization degradation value Qcur can be obtained by, for example, Qcur=K2×√(t). The coefficient K2 is a function of SOC. Assuming that SOH at the start point of the predetermined period is SOH1 and SOH at the end point is SOH2, SOH can be estimated by SOH2=SOH1−Qdeg.

Thus, SOH after the lapse of the predetermined period in the future can be estimated. Further, when the degradation value after the lapse of the predetermined period is calculated on the basis of the estimated SOH, SOH after the lapse of the predetermined period can be further estimated. By repeating the estimation of SOH every predetermined period, it is possible to estimate whether or not the energy storage device has reached the expected life (e.g., 10 years, 15 years, etc.) of the energy storage device (whether or not SOH is equal to or less than the end of life (EOL)).

The action generator may include a temperature information acquisition unit that acquires ambient temperature information of the energy storage device, and the SOH estimation unit may estimate SOH of the energy storage device on the basis of the ambient temperature information.

The temperature information acquisition unit acquires ambient temperature information of the energy storage device. The ambient temperature information is information representing the transition of the ambient temperature over a predetermined period of time.

The SOH estimation unit estimates SOH of the energy storage device on the basis of the estimated SOC transition and the ambient temperature information. The state acquisition unit acquires SOH estimated by the SOH estimation unit. A degradation value Qdeg of the energy storage device after the predetermined period can be expressed by the sum of an energization degradation value Qcur and a non-energization degradation value Qcnd. When the elapsed time is represented by t, the non-energization degradation value Qcnd can be obtained by, for example, Qcnd=K1×√(t). The coefficient K1 is a function of SOC and a temperature T. The energization degradation value Qcur can be obtained by, for example, Qcur=K2×√(t). The coefficient K2 is a function of SOC and the temperature T. Assuming that SOH at the start point of the predetermined period is SOH1 and SOH at the end point is SOH2, SOH can be estimated by SOH2=SOH1−Qdeg.

Thus, SOH after the lapse of the predetermined period in the future can be estimated. Further, when the degradation value after the lapse of the predetermined period is calculated on the basis of the estimated SOH, SOH after the lapse of the predetermined period can be further estimated. By repeating the estimation of SOH every predetermined period, it is possible to estimate whether or not the energy storage device has reached the expected life (e.g., 10 years, 15 years, etc.) of the energy storage device (whether or not SOH is equal to or less than the end of life (EOL)).

The action generator may include a reward calculation unit that calculates a reward on the basis of an amount of electric power sold to the power generating facility or the power demand facility, and the reward acquisition unit may acquire the reward calculated by the reward calculation unit.

The reward calculation unit calculates a reward on the basis of the amount of electric power sold to the power generating facility or the power demand facility. For example, in the case of an operation in which surplus power stored in the energy storage device is actively sold, the reward is calculated such that the larger the amount of electric power sold, the larger the value of the reward. Thereby, the optimum operation of the power system for electric power selling use can be achieved.

Further, in the case of an operation in which the surplus power stored in the energy storage device is not sold as much as possible, the reward is calculated such that the smaller the amount of electric power sold, the larger the value of the reward. Hence it is possible to achieve the optimum operation of the power system for the self-sufficient use of the electric power.

The action generator may include a reward calculation unit that calculates a reward on the basis of the power consumption amount resulting from the execution of the action, and the reward acquisition unit may acquire the reward calculated by the reward calculation unit.

The reward calculation unit calculates the reward on the basis of the power consumption amount resulting from the execution of the action. The power consumption amount resulting from the execution of the action is, for example, power consumption resulting from the setting of the SOC adjustment amount, the setting of the ambient temperature, and the like, and can be calculated by a function using the SOC adjustment amount, the ambient temperature, and the like as variables. For example, when the SOC adjustment amount is large, the reward can be a negative value (penalty). Hence it is possible to achieve the optimum operation of the energy storage device while reducing the power consumption amount.

The action generator may include a reward calculation unit that calculates a reward on the basis of whether or not the state of the energy storage device has reached the life, and the reward acquisition unit may acquire the reward calculated by the reward calculation unit.

The reward calculation unit calculates the reward on the basis of whether or not the state of the energy storage device has reached the life. For example, when SOH of the energy storage device is not less than the end of life (EOL), a reward can be given, and when SOH becomes equal to or less than EOL, a penalty can be given. It is thereby possible to achieve the optimum operation such that the expected life (e.g., 10 years, 15 years, etc.) of the energy storage device is reached.

An energy storage device evaluator includes: a learned model that includes updated action evaluation information; a state acquisition unit that acquires a state including SOH of an energy storage device; and an evaluation generation unit that inputs the state acquired by the state acquisition unit to the learned model and generates an evaluation result of the energy storage device on the basis of an action that includes setting related to SOC of the energy storage device output by the learned model.

A computer program causes a computer to execute the processing of: acquiring a state that includes a state of health (SOH) of a storage device; inputting the acquired state into a learned model that includes updated action evaluation information; and generating an evaluation result of the energy storage device on the basis of an action that includes setting related to SOC of the energy storage device output by the learned model.

An evaluation method includes: acquiring a state that includes a state of health (SOH) of a storage device; inputting the acquired state into a learned model that includes updated action evaluation information; and generating an evaluation result of the energy storage device on the basis of an action that includes setting related to SOC of the energy storage device output by the learned model.

The learned model includes updated, that is, learned, action evaluation information. When the state including SOH of the energy storage device acquired by the state acquisition unit is input to the learning model, the learning model outputs an action corresponding to the system operation including the energy storage device. The evaluation generation unit generates an evaluation result of the energy storage device on the basis of the action of the energy storage device output by the learning model. The evaluation result includes, for example, the optimum operation method of the entire system including the energy storage device in consideration of the health of the energy storage device.

The energy storage device evaluator includes a parameter acquisition unit that acquires a design parameter of the energy storage device, and the evaluation generation unit generates an evaluation result of the energy storage device in accordance with the design parameter acquired by the parameter acquisition unit.

The evaluation generation unit generates an evaluation result of the energy storage device in accordance with the design parameter acquired by the parameter acquisition unit. The design parameters of the energy storage devices include various parameters, such as the type, number, and rating of the energy storage devices, which are necessary for system design prior to an actual operation of the system. By generating the evaluation result of the energy storage device in accordance with the design parameter, it is possible to grasp, for example, what kind of design parameter is adopted to obtain the optimum operation method of the entire system in consideration of the health.

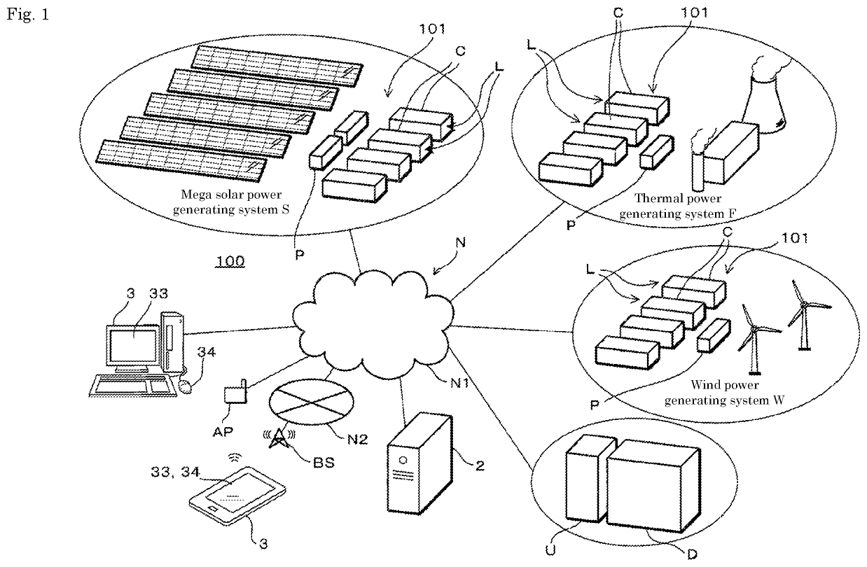

Hereinafter, the action generator and the energy storage device evaluator according to the present embodiment will be described with reference to the drawings. FIG. 1 is a diagram showing an outline of a remote monitoring system 100. As shown in FIG. 1, a network N includes a public communication network (e.g., the Internet) N1, a carrier network N2 that achieves wireless communication based on a mobile communication standard, and the like. A thermal power generating system F, a mega solar power generating system S, a wind power generating system W, an uninterruptible power supply apparatus, an uninterruptible power supply (UPS) U, a rectifier (d.c. power supply or a.c. power supply) D disposed in a stabilized power supply system for railways, and the like are connected to the network N. A communication device 1 to be described later, a server apparatus 2 as an action generator for collecting information from the communication apparatus 1, and a client apparatus 3 that acquires the collected information are connected to the network N.

More specifically, the carrier network N2 includes a base station BS. The client apparatus 3 can communicate with the server apparatus 2 from the base station BS via the network N. An access point AP is connected to the public communication network N1, and the client apparatus 3 can transmit and receive information to and from the server apparatus 2 via the network N from the access point AP.

The mega solar power generating system S, the thermal power generating system F, and the wind power generating system W are juxtaposed with a power conditioner (power conditioning system: PCS) P and an energy storage system 101. The energy storage system 101 is configured by juxtaposing a plurality of containers C each housing an energy storage module group L. The energy storage module group L has a hierarchical structure of, for example, an energy storage module (also called a module) in which a plurality of energy storage cells (also called a cell) are connected in series, a bank in which a plurality of energy storage modules are connected in series, and a domain in which a plurality of banks are connected in parallel. The energy storage device is preferably rechargeable, such as a secondary battery like a lead-acid battery or a lithium ion battery, or a capacitor. A part of the energy storage device may be a primary battery that is not rechargeable. The mega solar power generating system S, the thermal power generating system F, the wind power generating system W, the power conditioner P, and the energy storage system 101 supply electric power to a power demand facility through a power transmission and distribution network (not shown). The power system includes a power generating facility, a power demand facility, and the like which are connected to the energy storage system 101.

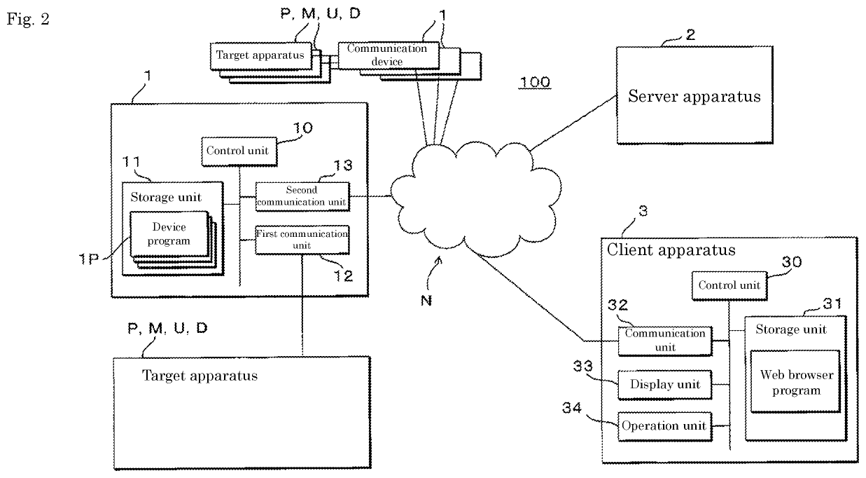

FIG. 2 is a block diagram showing an example of the configuration of the remote monitoring system 100. The remote monitoring system 100 includes the communication device 1, the server apparatus 2, the client apparatus 3, and the like.

As shown in FIG. 2, the communication device 1 is connected to the network N and is also connected to the target apparatuses P, U, D, M. The target apparatuses P, U, D, M include a power conditioner P, an uninterruptible power supply U, a rectifier D, and a management apparatus M to be described later.

In the remote monitoring system 100, the state (e.g., voltage, current, temperature, state of charge (SOC)) of the energy storage module (energy storage cell) in the energy storage system 101 is monitored and collected using the communication device 1 connected to each of the target apparatuses P, U, D, M. The remote monitoring system 100 presents the detected state (including a degraded state, an abnormal state, etc.) of the energy storage cell so that a user or an operator (a person in charge of maintenance) can confirm the detected state.

The communication device 1 includes a control unit 10, a storage unit 11, a first communication unit 12, and a second communication unit 13. The control unit 10 is made of a central processing unit (CPU) or the like and controls the entire communication device 1 by using built-in memories such as read-only memory (ROM) and random-access memory (RAM).

As the storage unit 11, for example, a nonvolatile memory such as a flash memory can be used. The storage unit 11 stores a device program 1P to be read and executed by the control unit 10. The storage unit 11 stores information such as information collected by the processing of the control unit 10 and event logs.

The first communication unit 12 is a communication interface for achieving communication with the target apparatuses P, U, D, M and can use, for example, a serial communication interface such as RS-232 C or RS-485.

The second communication unit 13 is an interface for achieving communication via the network N and uses, for example, a communication interface such as Ethernet (registered trademark) or a wireless communication antenna. The control unit 10 can communicate with the server apparatus 2 via the second communication unit 13.

The client apparatus 3 may be a computer used by the operator such as the administrator of the energy storage system 101 of the power generating systems S, F or a person in charge of maintenance of the target apparatuses P, U, D, M. The client apparatus 3 may be a desktop type or a laptop type personal computer or may be a smartphone or a tablet type communication terminal. The client apparatus 3 includes a control unit 30, a storage unit 31, a communication unit 32, a display unit 33, and an operation unit 34.

The control unit 30 is a processor using a CPU. The control unit 30 causes the display unit 33 to display a Web page provided by the server apparatus 2 or the communication device 1 on the basis of a Web browser program stored in the storage unit 31.

The storage unit 31 uses a nonvolatile memory such as a hard disk or a flash memory. The storage unit 31 stores various programs including a Web browser program.

The communication unit 32 can use a communication device such as a network card for wired communication, a wireless communication device for mobile communication connected to a base station BS (c.f. FIG. 1), or a wireless communication device corresponding to connection to the access point AP. The control unit 30 enables communication connection or transmission and reception of information between the server apparatus 2 or the communication device 1 via the network N by the communication unit 32.

As the display unit 33, a liquid crystal display, an organic electroluminescence (EL) display, or the like can be used. The display unit 33 can display an image of a Web page provided by the server apparatus 2 by processing based on the Web browser program of the control unit 30.

The operation unit 34 is a user interface, such as a keyboard and a pointing device, capable of input and output with the control unit 30 or a voice input unit. The touch panel of the display unit 33 or a physical button provided in the housing may be used for the operation unit 34. The operation unit 34 notifies the control unit 20 of the information of operation by the user.

The configuration of the server apparatus 2 will be described later.

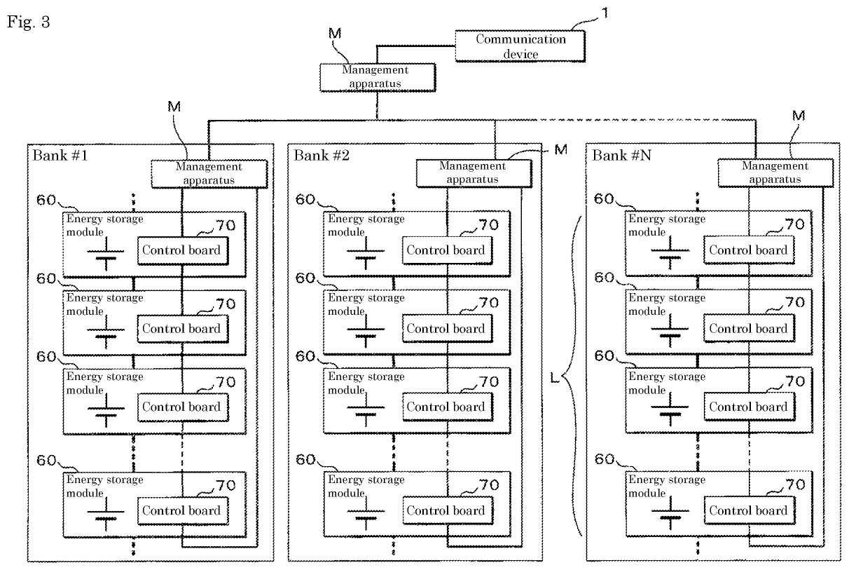

FIG. 3 is a diagram showing an example of the connection mode of a communication device 1. As shown in FIG. 3, the communication device 1 is connected to the management apparatus M. Management apparatuses M provided in banks #1 to #N, respectively, are connected to the management apparatus M. Note that the communication device 1 may be a terminal apparatus (measurement monitor) that communicates with the management apparatuses M provided in each of the banks #1 to #N to receive information on the energy storage devices, or may be a network card type communication device that can be connected to a power-supply-related apparatus.

Each of the banks #1 to #N includes a plurality of energy storage modules 60, and each energy storage module 60 comprises a control board (cell monitoring unit: CMU) 70. The management apparatus M provided for each bank can communicate with the control board 70 with a communication function built in each energy storage module 60 by serial communication, and can transmit and receive information to and from the management apparatus M connected to a communication device 1. The management apparatus M connected to the communication device 1 aggregates information from each management apparatus M of the bank belonging to a domain and outputs the aggregated information to the communication device 1.

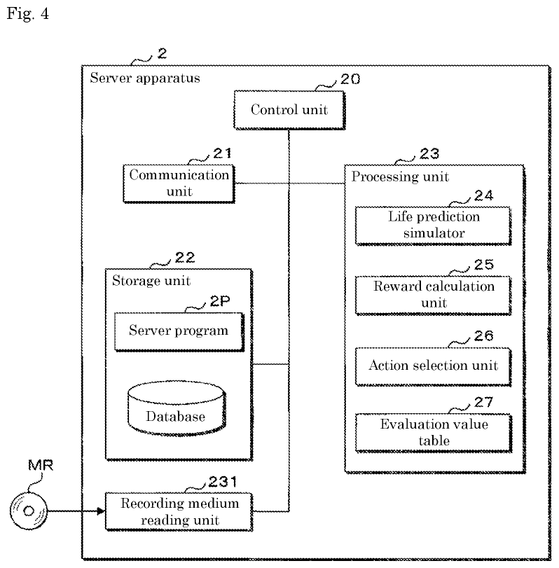

FIG. 4 is a block diagram showing an example of the configuration of the server apparatus 2. The server apparatus 2 includes a control unit 20, a communication unit 21, a storage unit 22, and a processing unit 23. The processing unit 23 includes a life prediction simulator 24, a reward calculation unit 25, an action selection unit 26, and an evaluation value table 27. The server apparatus 2 may be one server computer or may alternatively be made up of a plurality of server computers.

The control unit 20 can be made of, for example, a CPU, and controls the entire server apparatus 2 by using built-in memories such as ROM and RAM. The control unit 20 executes information processing based on a server program 2P stored in the storage unit 22. The server program 2P includes a Web server program, and the control unit 20 functions as a Web server that performs provision of a Web page to the client apparatus 3, reception of a login to a Web service, and the like. The control unit 20 can also collect information from the communication device 1 as a simple network management protocol) (SNMP) server based on the server program 2P.

The communication unit 21 is a communication device that achieves the communication connection and the transmission and reception of data via the network N. Specifically, the communication unit 21 is a network card corresponding to the network N.

As the storage unit 22, a nonvolatile memory such as a hard disk or a flash memory can be used. The storage unit 22 stores sensor information (e.g., voltage data, current data, and temperature data of the energy storage device) that includes the states of the target apparatuses P, U, D, M to be monitored and is collected by the processing of the control unit 20.

The storage unit 22 stores power consumption amount information in the power system to which the energy storage system 101 is connected. The power systems include power generating facilities such as the mega solar power generating system S, the thermal power generating system F, and the wind power generating system W, as well as power demand facilities. The power consumption amount information is information representing the transition of power consumption over a predetermined period. The predetermined period can be set to, for example, one day, one week, one month, spring, summer, autumn, winter, one year, or the like. The power consumption amount information is information representing a load pattern requested by a user using the energy storage system 101. Note that the power consumption amount information can be divided into banks and stored, for example, and common power consumption amount information for each bank can be used for the energy storage devices (battery cell) constituting the bank. The power consumption amount information includes both past results and future forecasts.

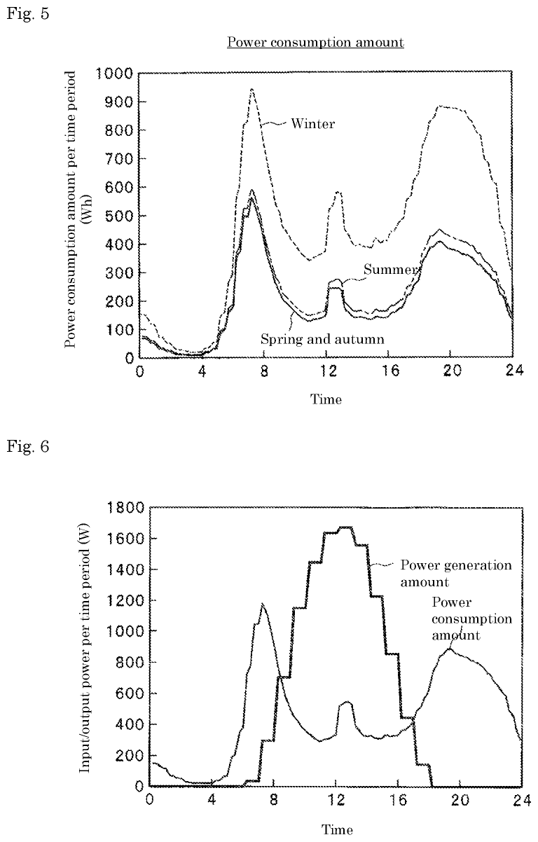

FIG. 5 is a schematic diagram showing an example of the power consumption amount information. In FIG. 5, the horizontal axis represents time, and the vertical axis represents a power consumption amount per time period. FIG. 5 shows the transition of a daily power consumption amount in each of spring, summer, autumn, and winter. In the power consumption pattern shown in FIG. 5 (also referred to as load pattern), the peaks of the power consumption appear around 7 to 8 a.m., around noon, and around 8 p.m. The power consumption pattern may alternatively be different from the example of FIG. 5.

The storage unit 22 stores power generation amount information in the power system to which the energy storage system 101 is connected. The power generation amount information is information representing the transition of generated power over a predetermined period. The predetermined period can be set to one day, one week, one month, spring, summer, autumn, winter, one year, or the like, similarly to the case of the power consumption amount information. Here, the power generation amount refers to the amount of electric power generated by renewable energy or an existing power generating system. The power generating system may be an electric power company or a large commercial (civilian) power generating facility, a business office, a building, a public facility such as a commercial facility, a government office, or a railway (station building), or a small power generating facility such as a household generating system. Note that the power generation amount information can be divided into banks and stored, for example, and power generation amount information for each bank can be used for the energy storage devices (battery cell) constituting the bank. The power generation amount information includes both past results and future forecasts.

FIG. 6 is a schematic diagram showing an example of the power generation amount information. In FIG. 6, the horizontal axis represents time, and the vertical axis represents a power generation amount per time period. Note that FIG. 6 is shown such that the difference between the amount of electric power generated by the photovoltaic power generation and the power consumption amount can be seen. The input/output power shown in FIG. 6 shows a case in summer. In the power generation amount pattern shown in FIG. 6, the peak of the power generation amount appears in the daytime (especially around noon). The power generation amount pattern may alternatively be different from the example of FIG. 6.

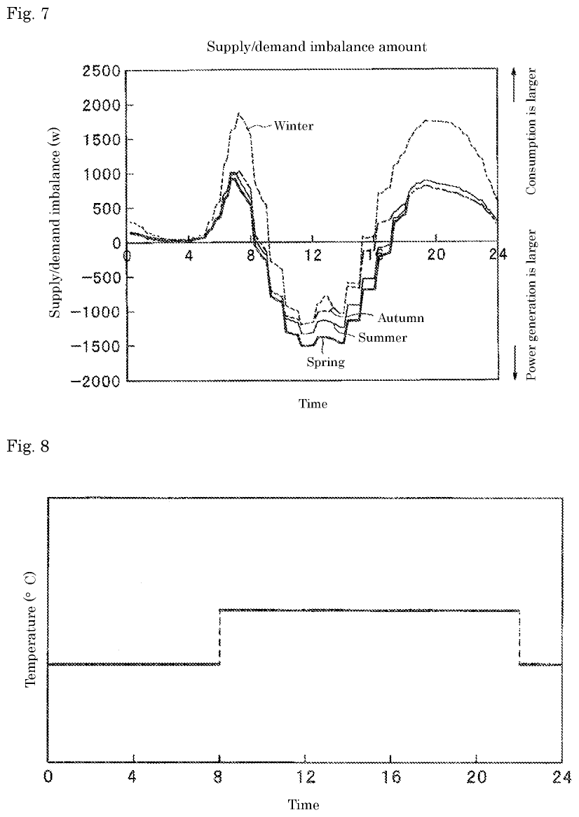

FIG. 7 is a schematic diagram showing an example of the transition of a supply/demand imbalance amount of electric power in each season. In FIG. 7, the horizontal axis represents time, and the vertical axis represents the supply/demand imbalance amount. When the supply/demand imbalance amount is positive, it indicates that consumption is larger, and when the supply/demand imbalance amount is negative, it indicates that power generation is larger. As shown in FIG. 7, the supply/demand imbalance can be absorbed by, for example, the charge and discharge of the energy storage system 101 provided in the photovoltaic power generating facility.

The storage unit 22 stores ambient temperature information in the energy storage system 101. The ambient temperature information is information representing the transition of the ambient temperature over a predetermined period of time. Note that the ambient temperature information can be divided into banks and stored, and for the energy storage devices (battery cells) constituting the bank, the ambient temperature corrected by the arrangement of the energy storage devices can be used. The ambient temperature information includes both past results and future forecasts. For example, prediction data of future weather conditions can be added to further improve the estimation accuracy.

FIG. 8 is a schematic diagram showing an example of the ambient temperature information. In FIG. 8, the horizontal axis represents time, and the vertical axis represents temperature. FIG. 8 shows transition of daily ambient temperature. In the temperature pattern shown in FIG. 8, the temperature is slightly higher in the daytime and lower at night, but the temperature pattern may alternatively be different from the example of FIG. 8.

The processing unit 23 can acquire sensor information (voltage data in time series, current data in time series, temperature data in time series) of the energy storage devices (energy storage modules, energy storage cells) collected in the database of the storage unit 22, by classifying the information into each energy storage device.

The processing unit 23 can acquire the power consumption amount information, the power generation amount information, and the ambient temperature information described above from the storage unit 22.

In the processing unit 23, the reward calculation unit 25, the action selection unit 26, and the evaluation value table 27 constitute a function for performing reinforcement learning. The processing unit 23 performs reinforcement learning by using the degradation value of the energy storage device (which can be replaced with the state of health (SOH) of the storage device) output from the life prediction simulator 24, so that it is possible to obtain an optimum operating conditions for reaching the expected life (e.g., 10 years, 15 years, etc.) of the energy storage device. The details of the processing unit 23 will be described below.

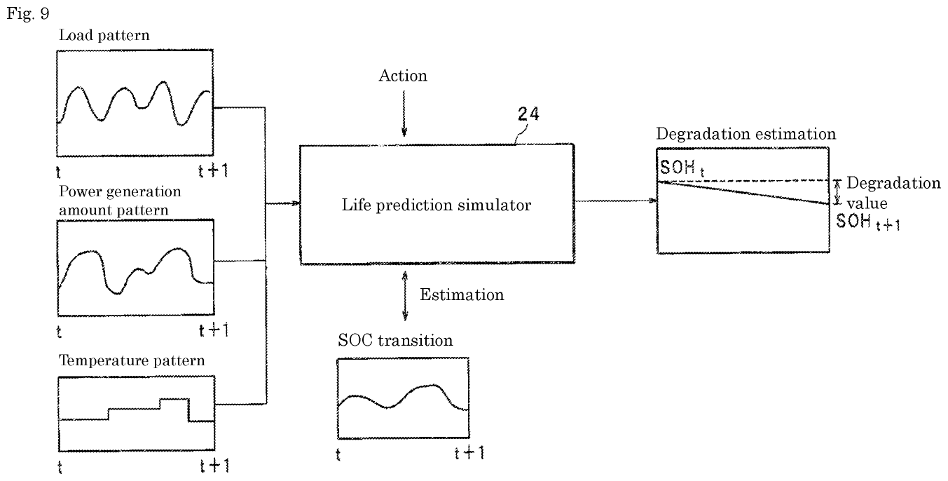

FIG. 9 is a schematic diagram showing the operation of the life prediction simulator 24. A life prediction simulator 24 acquires a load pattern (power consumption amount information), a power generation amount pattern (power generation amount information), and a temperature pattern (ambient temperature information) as input data. The life prediction simulator 24 estimates the SOC transition of the energy storage device and estimates (calculates) the degradation value of the energy storage device. The life prediction simulator 24 can acquire the action selected by the action selection unit 26, estimate the SOC transition of the energy storage device, and estimate the degradation value of the energy storage device.

When SOH (also referred to as health) at time point t is defined as SOHₜ, and SOH at time point t+1 is defined as SOHₜ₊₁, the degradation value is (SOHₜ−SOHₜ₊₁). Here, the time point can be a given time point at present or in the future, and time point t+1 can be a time point at which a required time has elapsed from time point t toward the future. The time difference between time point t and time point t+1 is the life prediction target period of the life prediction simulator 24 and can be appropriately set in accordance with how much future the life is predicted. The time difference between time point t and time point t+1 can be a required time, such as one month, half year, one year, or two years.

When the period from the start point to the end point of the load pattern, the power generation amount pattern, or the temperature pattern is shorter than the life prediction target period of the life prediction simulator 24, for example, the load pattern, the power generation amount pattern, or the temperature pattern can be repeatedly used over the life prediction target period.

The life prediction simulator 24 has a function as the SOC transition estimation unit and estimates the transition of SOC of the energy storage device on the basis of the power generation amount pattern, the load pattern, and the action selected by the action selection unit 26. When the generated power is larger than the power consumption in the life prediction target period, the energy storage device is charged, and SOC increases. On the other hand, when the generated power is smaller than the power consumption, the energy storage device is discharged, and SOC decreases. In the life prediction target period, the charge and discharge of the energy storage device may not be performed (e.g., at night.). The fluctuation of SOC is limited by the upper limit value and the lower limit value of SOC. With the SOC adjustment amount, SOC can be increased. Thus, the life prediction simulator 24 can estimate the transition of SOC over the life prediction target period.

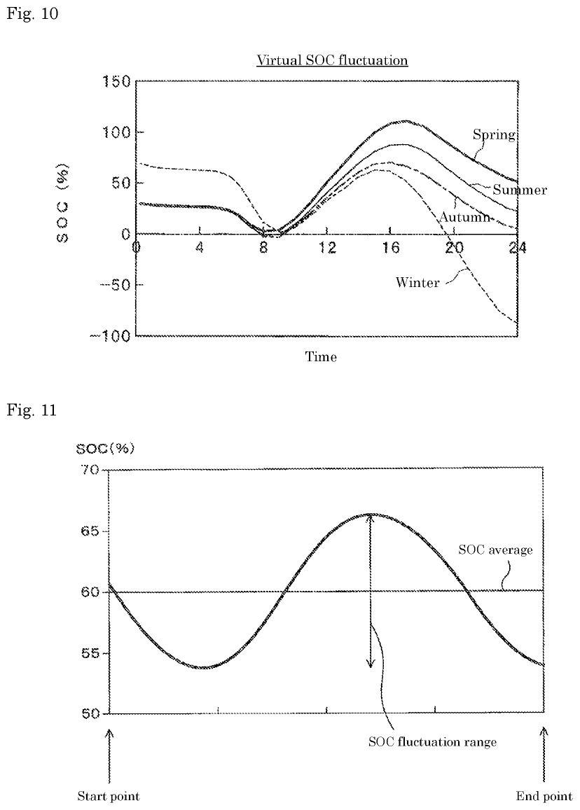

FIG. 10 is a schematic diagram showing an example of a virtual SOC fluctuation. In FIG. 10, the horizontal axis represents time, and the vertical axis represents SOC. The SOC fluctuation in each season shown in FIG. 10 corresponds to the SOC transition as a result of charging and discharging the energy storage device to absorb the seasonal supply/demand imbalance shown in FIG. 7. In FIG. 10, the action selected by the action selection unit 26 is omitted for convenience.

FIG. 11 is a schematic diagram showing an example of a feature amount of SOC. In FIG. 11, the horizontal axis represents time, and the vertical axis represents SOC. In the figure, the fluctuation of SOC is sinusoidal for convenience, but the actual fluctuation of SOC may not be sinusoidal. The start point can be set as time t, and the end point can be set as time point t+1. The feature amount of SOC affects the degradation (or SOH) of the energy storage device and includes, for example, an SOC average (also referred to as central SOC), an SOC fluctuation range, and the like. The central SOC is a value obtained by dividing a value, obtained by sampling and summing SOC values from the start point to the end point, by the number of samples. The SOC fluctuation range is the difference between the maximum and minimum SOC values from the start point to the end point.

The life prediction simulator 24 can estimate the temperature of the energy storage device on the basis of the ambient temperature of the energy storage device.

The life prediction simulator 24 has a function as the SOH estimation unit and estimates SOH of the energy storage device on the basis of the estimated SOC transition and the temperature of the energy storage device. The degradation value Qdeg after the lapse of the life prediction target period (e.g., from time point t to time point t+1) of the energy storage device can be calculated by Equation (1):

$$\begin{matrix}[ Math . 1 ] & \\ \begin{matrix}Q deg = Qcnd + Qcur \\ = K 1 ( soc , T ) \times \sqrt{t} + K 2 ( soc , T ) \times \sqrt{t}\end{matrix} & ( 1 )\end{matrix}$$

Here, Qcnd is a non-energization degradation value, and Qcur is an energization degradation value. As shown in Equation (1), the non-energization degradation value Qcnd can be obtained by, for example, Qcnd=K1×√(t). The coefficient K1 is a function of SOC and a temperature T. “t” is an elapsed time, for example, the time from time point t to time point t+1. The energization degradation value Qcur can be obtained by, for example, Qcur=K2×√(t). The coefficient K2 is a function of SOC and the temperature T. Assuming that the SOH at time point t is SOHₜ and the SOH at time point t+1 is SOHₜ₊₁, the SOH can be estimated by SOHₜ₊₁=SOHₜ-Qdeg.

The coefficient K1 is a degradation coefficient, and the correspondence relation between each of the SOC and the temperature T, and the coefficient K1 can be obtained by calculation or stored in a table form. SOC includes, for example, feature amounts such as the central SOC and the SOC fluctuation range. The coefficient K2 is the same as the coefficient K1.

As described above, the life prediction simulator 24 can estimate SOH after the lapse of the future life prediction target period. Further, when the degradation value after the lapse of the life prediction target period is calculated on the basis of the estimated SOH, SOH after the lapse of the life prediction target period can be further estimated. By repeating the estimation of SOH every life prediction target period, it is possible to estimate whether or not the energy storage device has reached the expected life (e.g., 10 years, 15 years, etc.) of the energy storage device (whether or not SOH is equal to or less than the end of life (EOL)).

The following two virtual examples are considered as the operation mode of the power system. The first example is a mode in which charge (auxiliary charge) is performed from the power system to the energy storage system 101 at night, and surplus power is sold from day to night (an example of an operation for electric power selling use), and the second example is a mode in which the electric energy storage system 101 is caused to absorb all of the supply/demand imbalance amount, and no electric power is sold or bought (an example of an operation for self-sufficient power supply). First, reinforcement learning of the operation method in the operation example for electric power selling use in the first example will be described.

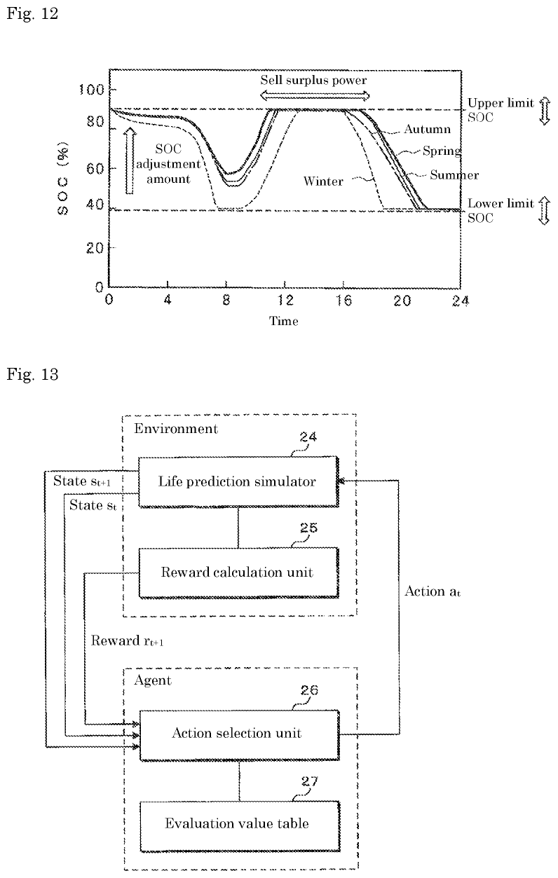

FIG. 12 is a schematic diagram showing an example of the setting related to SOC in an example of the operation for power selling use. In FIG. 12, the horizontal axis represents time, and the vertical axis represents SOC, representing the transition of SOC in a day from 0 o'clock to 24 o'clock for each season. In FIG. 12, at night, the charge (auxiliary charge) is performed from the power system to the energy storage system 101, and the SOC adjustment amount is set so as to set SOC of the energy storage device to a required value. In order to sell surplus power, the range between the upper limit value and the lower limit value of SOC is narrowed. Specifically, the lower limit value of SOC is set to a large value so that the residual capacity of the energy storage device is not reduced. Reinforcement learning in the present embodiment is, for example, learning what kind of SOC related setting is to be made as an action to achieve an optimum operation method. The details of reinforcement learning will be described below.

FIG. 13 is a schematic diagram showing an example of reinforcement learning. Reinforcement learning is a machine learning algorithm that obtains a strategy (a rule serving as an indicator when the agent acts) with which an agent in a given environment takes action relative to the environment to maximize the reward obtained (a rule serving as an indicator when the agent acts). In reinforcement learning, the agent is like a learner who takes action on the environment and is a learning target. In response to the action of the agent, the environment updates the state and gives a reward. The action is an action that the agent can take for a given state of the environment. The state is the state of the environment that the environment holds. The reward is given to the agent when the agent causes a desired result to act on the environment. The reward can be, for example, a positive, negative, or zero value. The reward is the reward itself when being a positive value, the reward is a penalty when being a negative value, and there is no reward when the reward is a zero value. An action evaluation function is a function for determining an evaluation value of an action in a given state, can be expressed in a table form such as a table, and is referred to as a Q-function, a Q-value, an evaluation value, and the like in Q-learning. Q-learning is one of the methods often used in reinforcement learning. Although Q-learning will be described below, reinforcement learning may alternatively be different from Q-learning.

In the processing unit 23 of the present embodiment, the life prediction simulator 24 and the reward calculation unit 25 correspond to the environment, and the action selection unit 26 and the evaluation value table 27 correspond to the agent. The evaluation value table 27 corresponds to the Q-function described above and is also referred to as action evaluation information.

The action selection unit 26 selects an action including the setting related to SOC for a state including the state of health (SOH) of the energy storage device, on the basis of the evaluation value table 27. In the example of FIG. 13, the action selection unit 26 acquires a state sₜ (e.g., SOHₜ) at time point t from the life prediction simulator 24 and selects and outputs an action aₜ. As described above, the setting related to SOC includes, for example, setting of an upper limit value of SOC (to avoid overcharge of the energy storage device), a lower limit value of SOC (to avoid overdischarge of the energy storage device), an SOC adjustment amount for setting SOC of the energy storage device to a required value (to charge the energy storage device in advance), and the like. The action selection unit 26 can select an action having the highest evaluation (e.g., the highest Q-value) in the evaluation value table 27.

The action selection unit 26 has a function as the state acquisition unit and acquires the state of the energy storage device when the selected action is executed. When the action selected by the action selection unit 26 is executed by the life prediction simulator 24, the state of the environment changes. Specifically, the life prediction simulator 24 outputs the state sₜ₊₁ (e.g., SOHₜ₊₁) at time point t+1, and the state is updated from sₜ to sₜ₊₁. Then action selection unit 26 acquires the updated state. The action selection unit 26 has a function as the reward acquisition unit and acquires a reward calculated by the reward calculation unit 25.

The reward calculation unit 25 calculates a reward when the selected action is executed. When the action selection unit 26 causes a desired result to act on the life prediction simulator 24, a high value (positive value) is calculated. When the reward is 0, there is no reward, and when the reward is a negative value, there is a penalty. In the example of FIG. 13, the reward calculation unit 25 gives a reward rₜ₊₁ to the action selection unit 26.

The reward calculation unit 25 may calculate the reward on the basis of the amount of electric power sold to the power system. For example, in the case of an operation in which surplus power stored in the energy storage device is actively sold, the reward is calculated such that the larger the amount of electric power sold, the larger the value of the reward. Thereby, the optimum operation of the power system for electric power selling use can be achieved.

The reward calculation unit 25 calculates the reward on the basis of the power consumption amount resulting from the execution of the action. The power consumption amount resulting from the execution of the action is, for example, power consumption resulting from the setting of the SOC adjustment amount, the setting of the ambient temperature, and the like, and can be calculated by a function using the SOC adjustment amount, the ambient temperature, and the like as variables. For example, when the SOC adjustment amount is large, the reward can be a negative value (penalty). Hence it is possible to achieve the optimum operation of the energy storage device while reducing the power consumption amount.

The reward calculation unit 25 may calculate the reward on the basis of whether or not the state of the energy storage device has reached the life. For example, when SOH of the energy storage device is not less than the end of life (EOL), a reward can be given, and when SOH becomes equal to or less than EOL, a penalty can be given. It is thereby possible to achieve the optimum operation such that the expected life (e.g., 10 years, 15 years, etc.) of the energy storage device is reached.

The action selection unit 26 has a function as the updating unit and updates the evaluation value table 27 on the basis of the acquired state sₜ₊₁ and reward rₜ₊₁ . More specifically, the action selection unit 26 updates the evaluation value table 27 in the direction of maximizing the reward for the action. This enables learning of an action that is expected to have the greatest value in a given state of the environment.

By repeating the processing described above to repeat the update of the evaluation value table 27, it is possible to learn the evaluation value table 27 capable of maximizing the reward.

The processing unit 23 has a function as the action generation unit, and on the basis of the updated evaluation value table 27 (i.e., learned evaluation value table 27), the processing unit 23 generates an action (specifically, operation information) corresponding to the system operation including the state of the energy storage device. Thus, for various states (e.g., various SOH) of the energy storage device, for example, the optimum value of the setting related to SOC can be obtained by reinforcement learning, so that the optimum operation of the system including the energy storage device can be achieved.

The update of the Q-function in Q-learning can be performed by Equation (2):

[Math. 2]

Q(sₜ,aₜ)←Q(sₜ,aₜ)+α{rₜ₊₁+γ·maxQ(sₜ₊₁,aᵢ₊₁)−Q(sₜ, aₜ)} (2)

Q(sₜ,aₜ)←Q(sᵢ,aₜ)+α{rₜ₊₁−Q(sₜ,aₜ)} (3)

Q(sₜ,aₜ)←Q(sₜ,aᵢ)+α{γ·maxQ(sₜ₊₁,aᵢ₊₁)−Q(sₜ,aᵢ)} (4)

Here, Q is a function or a table (e.g., evaluation value table 27) for storing the evaluation of the action a in the state s and can be expressed, for example, in the form of a matrix having each state s as a row and each action a as a column.

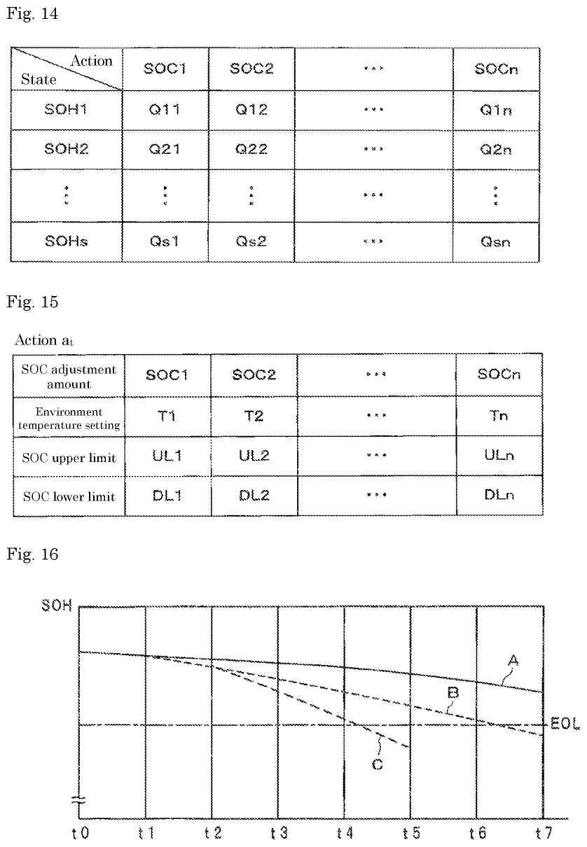

FIG. 14 is a schematic diagram showing an example of the configuration of the evaluation value table 27. As shown in FIG. 14, the evaluation value table 27 has a matrix form made up of each state (in the example of FIG. 14, SOH1, SOH2, . . . , SOHs as SOH of the energy storage device) and each action (in the example of FIG. 14, SOC1, SOC2, . . . , SOCn as the setting of the SOC adjustment amount), and the evaluation of the action in each state (in the example of FIG. 14, Q11, Q12, . . . , Qsn) is stored. The evaluation value table 27 shows an evaluation value when an action a, which can be taken in a given state s, is executed. The SOC adjustment amount can be appropriately set within the range between the upper limit value and the lower limit value of SOC and can be set at 1% intervals, for example, 50%, 51%, 52%, or at 5% intervals.

In Equation (2), sₜ represents a state at time point t, aₜ represents an action that can be taken in the state sₜ, a represents a learning rate (where 0<α<1), and γ represents a discount rate (where 0<γ<1). The learning rate α is also referred to as a learning coefficient and is a parameter for determining the speed (step size) of learning. That is, the learning rate α is a parameter for adjusting the updated amount of the evaluation value table 27. The discount rate γ is a parameter for determining how much the evaluation (reward or penalty) of the future state is discounted and considered at the time of updating the evaluation value table 27. That is, the discount rate γ is a parameter for determining how much the reward or penalty is discounted when the evaluation in a given state is linked to the evaluation in a past state.

In Equation (2), rₜ₊ is a reward obtained as a result of the action, and, rₜ₊₁ is 0 when no reward is obtained, and is a negative value in the case of a penalty. In Q-learning, the evaluation value table 27 is updated such that the second term {rₜ₊₁+γ·maxQ(sₜ₊₁,aₜ₊₁)−Q(sₜ, aₜ)} of Equation (2) becomes 0, that is, the value Q(sₜ,aₜ) of the evaluation value table 27 becomes the sum of the reward (rₜ₊₁) and the maximum value (γ/maxQ(sₜ₊₁, aₜ₊₁)) among possible actions in the next state sₜ₊₁. The evaluation value table 27 is updated such that the error between the expected value of the reward and the current action evaluation is brought closer to 0. In other words, the value of (γ/maxQ(sₜ₊₁, aₜ₊₁)) is modified on the basis of the value of the current Q(sₜ, aₜ) and the maximum evaluation value obtained among the actions executable in the state sₜ₊₁ after the action aₜ is executed.

The reward is not necessarily obtained when the action is executed in a given state. For example, the reward may be obtained after several times of repeated actions. Equation (3) represents an updated equation of the Q-function when the reward is obtained, and Equation (4) represents an updated equation of the Q-function when the reward is not obtained.

In the initial state of Q-learning, the Q-value of the evaluation value table 27 can be initialized by a random number, for example. Once there is a difference in the expected value of the reward in the initial stage of Q-learning, it is not possible to transition to a state that has not been experienced yet, and it is possible that the goal cannot be reached. Therefore, a probability can be used to determine an action for a given state. Specifically, an action can be selected and executed at random out of all actions at a given probability ε, and an action having the largest Q-value at a probability (1-ε) can be selected and executed. Hence it is possible to appropriately advance the learning regardless of the initial state of the Q-value.

The SOC adjustment amount is an adjustment amount for charging the energy storage device from the power system at night and setting SOC of the energy storage device to a required value before connecting the energy storage device to a load. For example, in a case where SOC of the energy storage device, which has 20% of SOC, is set to 90%, the SOC adjustment amount is 70% (=90-20). Thus, surplus power from day to night can be sold while the power demand of the load is satisfied, and the setting related to SOC capable of reducing the degree of degradation of the energy storage device can be learned while the power selling is considered. In addition, by using electric power, charged at night when the electricity rate is low, in the daytime, it is possible to learn how to operate a system that avoids buying electricity during the daytime when the electricity rate is high.

In the example of FIG. 14, the setting of the SOC adjustment amount has been described as the action, but the action also alternatively includes those other than the SOC adjustment amount.

FIG. 15 is a schematic diagram showing an example of the action. As shown in FIG. 15, in addition to the setting of the SOC adjustment amount, the action can include the setting of the ambient temperature, the setting of the SOC upper limit value, the setting of the SOC lower limit value, and the like. The ambient temperature may be set, for example, at intervals of 1° C. or at intervals of 5° C. The temperature interval can be set appropriately. When the ambient temperature is set, the temperature of the energy storage device can be estimated on the basis of the ambient temperature of the energy storage device. The degradation value of the energy storage device changes in accordance with the temperature of the energy storage device, so that it is possible to learn the setting of an ambient temperature that can reduce the degree of degradation in accordance with the state (e.g., SOH) of the energy storage device. On the other hand, the cost increases due to the consumption of electric power for adjusting the ambient temperature. With the present embodiment, it is possible to learn an ambient temperature setting to minimize such power consumption.

The upper limit value and the lower limit value of SOC can be set to appropriate values. The intervals of the set values may be set, for example, at intervals of 1% or at intervals of 5%. Setting the upper limit value of SOC can prevent the overcharge of the energy storage device. Setting the lower limit value of SOC can prevent the overdischarge of the energy storage device. Setting the upper limit value and the lower limit value of SOC can adjust the central SOC of SOC and the fluctuation range of SOC which change with the charge and discharge of the energy storage device. The center of SOC is the average of the changing SOC, and the fluctuation range of SOC is the difference between the maximum and minimum values of the changing SOC. The degradation value of the energy storage device changes in accordance with the center of SOC and the fluctuation range of SOC, so that it is possible to learn setting related to SOC which can reduce the degree of degradation in accordance with the state (e.g., SOH) of the energy storage device.

The action can include the setting of at least one of the SOC adjustment amount, the SOC upper limit value, the SOC lower limit value, and the ambient temperature. That is, the action may be a combination of some of the SOC adjustment amount, the SOC upper limit value, the SOC lower limit value, and the ambient temperature, or a combination of the all. The action may include the setting of the maximum current value, the upper and lower limit voltage values, and the like of the energy storage device.

In the example of FIG. 14, SOH has been described as the state, but the state also alternatively includes those other than SOH. For example, weather forecasts (sunny, cloudy, rainy, etc.), seasons (spring, summer, autumn, winter), and the like can be included. The weather forecast can be transitioned at random by a random number or the like. The season can be transitioned by period.

FIG. 16 is a schematic diagram showing an example of the state transition of reinforcement learning. For convenience, FIG. 16 shows eight time points of time point t0, t1, t2, . . . , t7. In actual reinforcement learning, the number of time points also alternatively include those other than the example of FIG. 16. Reference numerals A, B, and C represent examples of a learning process: the learning of reference numeral A shows a case where SOH has not reached EOL at time point t7 (the state as a result of the action being selected and executed at each time point); the learning of reference numeral B represents a case where SOH has not reached EOL at time point t6 but has fallen below EOL at time point t7; and the learning of reference numeral C represents a case where SOH has fallen below EOL at time point t5 and the learning has once ended. By reinforcement learning, the actions learned in reference numerals B and C are not adopted, and the action learned in reference A is adopted as an example of the operation method.

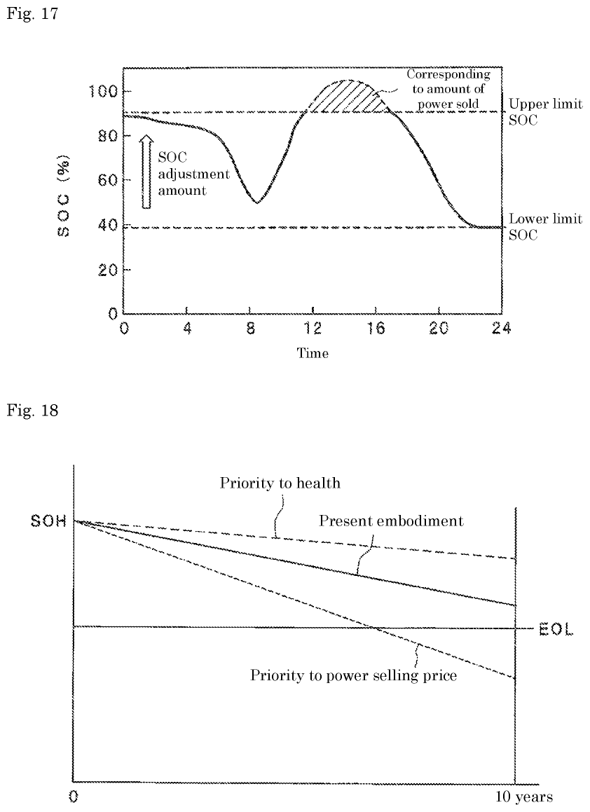

FIG. 17 is a schematic diagram showing an example of the operation method obtained by reinforcement learning. For convenience, FIG. 17 shows the operation method for one day from 0 o'clock to 24 o'clock, but the period also alternatively includes those other than one day. For example, one week, one month, three months, six months, one year, or the like may be used. The operation method as shown in FIG. 17 is appropriately changed in accordance with the load pattern of the user. In the example of FIG. 17, an operation method in which SOH of the energy storage device reaches the expected life (e.g., 10 years, 15 years) is shown. That is, the range between the upper limit value of SOC and the lower limit value of SOC is made relatively narrow (the lower limit value of SOC is made relatively a large value), the energy storage device is charged from the power system at night while the discharge amount of the energy storage device is reduced (the SOC adjustment amount is set), the lowering of SOC at the time when the energy storage device is connected to the load and used is prevented, and the surplus power can be sold as much as possible. In the figure, of the transition of SOC, a portion exceeding the upper limit SOC (shaded portion) corresponds to the amount of electric power sold.

FIG. 18 is a schematic diagram showing an example of the transition of SOH by the operation method obtained by reinforcement learning. In the example of FIG. 18, the expected life is ten years. In FIG. 18, a graph indicated by a solid line is according to the present embodiment, and graphs indicated by broken lines show, as comparative examples, a case where the power selling price is given priority and a case where the health is given priority. When the power selling price is given priority, the expected life may not be reached because the health of the energy storage device is not considered. When the health is given priority, the expected life can be sufficiently achieved, but the amount of electric power sold can be excessively small, and the amount of electric power purchased can be excessively large. In the present embodiment, since the reduction in SOH of the energy storage device is taken into consideration, it is possible to perform an optimum operation in which the amount of electric power sold can be increased while the expected life of the energy storage device can be achieved. Since the operation mode of the system varies depending on the user, when a case is assumed where the user gives priority to the health of the energy storage device, it is possible to use the operation method with priority given to the health of the energy storage device, shown in FIG. 18, and to expand the user's choice of the operation method.

Next, reinforcement learning of the operation method in the operation example for selling electric power use in the second example will be described.

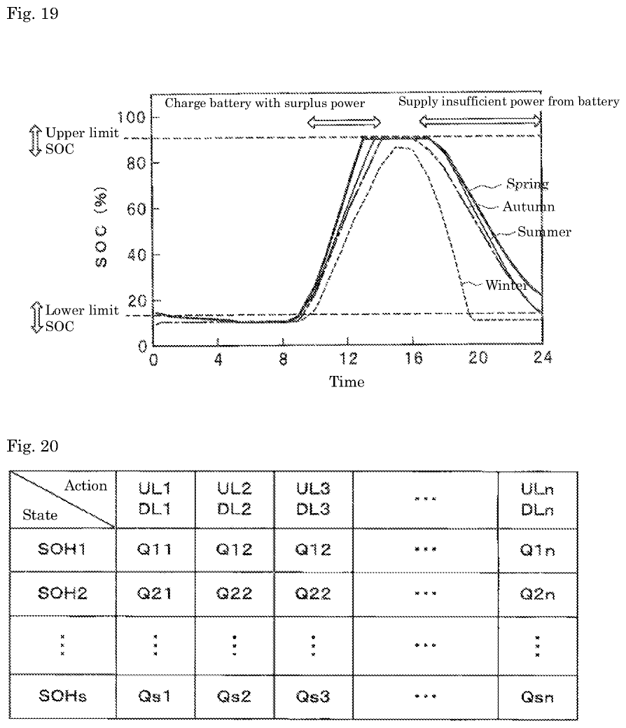

FIG. 19 is a schematic diagram showing an example of the setting related to SOC in an example of the operation for self-sufficient use. In FIG. 19, the horizontal axis represents time, and the vertical axis represents SOC, representing the transition of SOC in a day from 0 o'clock to 24 o'clock for each season. In FIG. 19, the range between the upper limit value and the lower limit value of SOC is widened such that the energy storage system 101 is charged with surplus power, insufficient power is supplied from the energy storage system 101, and surplus power is not sold as much as possible. Specifically, the lower limit value of SOC is set to a value as small as possible to use the capacity of the energy storage device as much as possible. The charge (auxiliary charge) is not performed from the power system to the energy storage system 101. Reinforcement learning in the present embodiment is, for example, learning what kind of SOC related setting is to be made as an action to achieve an optimum operation method. Hereinafter, among the details of reinforcement learning, points different from the first example will be described.

In the second example, the setting of the upper limit value of SOC and the setting of the lower limit value of SOC can each be used as the action.

FIG. 20 is a schematic diagram showing an example of the configuration of the evaluation value table 27 in the second example. As shown in FIG. 20, the evaluation value table 27 has a matrix form made up of each state (in the example of FIG. 20, SOH1, SOH2, . . . , SOHs as SOH of the energy storage device) and each action (in the example of FIG. 20, UL1 and DL1, UL2 and DL2, UL3 and DL3, . . . , ULn and DLn as a combination of an upper limit value UL of SOC and a lower limit value DL of SOC), and the evaluation of the action in each state (in the example of FIG. 20, Q11, Q12, . . . , Qsn) is stored. The upper limit value and the lower limit value of SOC can be set appropriately, for example, at 1% intervals.

In the example of the second example, the reward calculation unit 25 may calculate the reward on the basis of the amount of electric power sold to the power system. In the second example, in the case of an operation in which the surplus power stored in the energy storage device is not sold as much as possible, the reward is calculated such that the smaller the amount of electric power sold, the larger the value of the reward. Hence it is possible to achieve the optimum operation of the power system for the self-sufficient use of the electric power.

The reward calculation unit 25 calculates the reward on the basis of the power consumption amount resulting from the execution of the action. The power consumption amount resulting from the execution of the action is, for example, power consumption caused by the setting of the upper limit value and the lower limit value of SOC, or the like. In addition, it is also possible to give, as an example, power consumption caused by the energy storage device being unable to supply power to the system in response to power demand due to the high set value of the lower limit SOC. The reward calculation unit 25 can calculate such that the smaller the power consumption, the larger the reward. Hence it is possible to achieve the optimum operation of the energy storage device while reducing the power consumption amount.

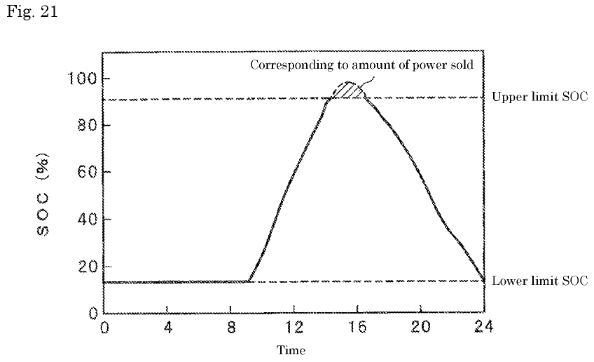

FIG. 21 is a schematic diagram showing an example of the operation method of the second example obtained by reinforcement learning. For convenience, FIG. 21 shows the operation method for one day from 0 o'clock to 24 o'clock, but the period also alternatively includes those other than one day. For example, one week, one month, three months, six months, one year, or the like may be used. The operation method as shown in FIG. 21 is appropriately changed in accordance with the load pattern of the user. In the example of FIG. 21, an operation method in which SOH of the energy storage device reaches the expected life (e.g., 10 years, 15 years) is shown. That is, the range between the upper limit value of SOC and the lower limit value of SOC is made relatively wide (the lower limit value of SOC is made relatively a small value) to the extent that SOH of the energy storage device reaches the expected life, and the energy storage device is actively charged and discharged so as not to cause overdischarge and overcharge, thereby supplying insufficient power while minimizing surplus power. In the figure, of the transition of SOC, a portion exceeding the upper limit SOC (shaded portion) corresponds to the amount of electric power sold.

Next, the processing of reinforcement learning will be described.

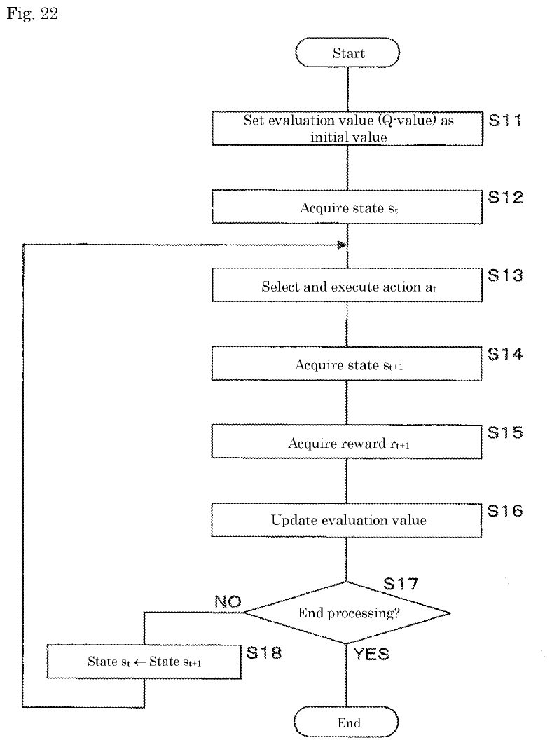

FIG. 22 is a flowchart showing an example of a processing procedure for reinforcement learning. The processing unit 23 sets the evaluation value (Q-value) of the evaluation value table 27 to an initial value (S11). For example, a random number can be used for setting the initial value. The processing unit 23 acquires a state sₜ (S12), and selects and executes an action aₜ that can be taken in the state sₜ (S13). The processing unit 23 acquires a state sₜ₊₁ obtained as a result of the action aₜ (S14) and acquires a reward rₜ₊₁ (S15). Note that the reward may be 0 (no reward).

The processing unit 23 uses Equation (3) or Equation (4) described above to update the evaluation value in the evaluation value table 27 (S16) and determines whether or not to end the processing (S17). Here, whether or not to end the processing can be determined on the basis of whether or not the evaluation value in the evaluation value table 27 has been updated a predetermined number of times, or on the basis of whether or not the state sₜ₊₁ has reached a predetermined state (e.g., a state where SOH of the energy storage device has reached EOL).

When the processing is not to be ended (NO at S17), the processing unit 23 sets the state st₊i to the state sₜ (S18) and continues the processing from step S13. When the processing is to be ended (YES in S17), the processing unit 23 ends the processing. Note that the processing shown in FIG. 22 can be repeated. The processing shown in FIG. 22 can be repeatedly performed using changed system design parameters each time the system design parameters of the energy storage device are changed. The details of the system design parameters of the energy storage device will be described later.

The processing unit 23 can be configured, for example, by combining hardware such as a CPU (e.g., multiple processors mounted with a plurality of processor cores, etc.), a graphics processing unit (GPU), a digital signal processor (DSP), a field-programmable gate array (FPGA), and the like. The processing unit 23 may be a virtual machine or a quantum computer. The agent is a virtual machine existing on a computer, and the state of the agent is changed by parameters or the like.

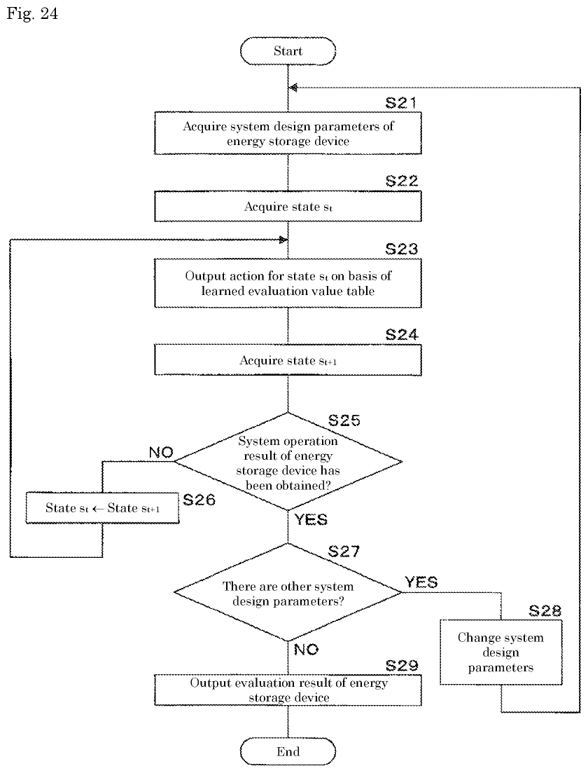

The control unit 20 and the processing unit 23 can be achieved using a general-purpose computer that includes a CPU (processor), a GPU, a RAM (memory), and the like. For example, a computer program and data (e.g., learned Q-function or Q-value) recorded on a recording medium MR as shown in FIG. 4 (e.g., an optically readable disk storage medium such as a compact disc read-only memory (CD-ROM)) can be read by the recording medium reading unit 231 (e.g., optical disk drive) and stored on the RAM. The computer program and data may be stored on a hard disk (not shown), and stored on the RAM when the computer program is executed. The control unit 20 and the processing unit 23 can be achieved on the computer by loading a computer program that determines the procedure for each processing, as shown in FIG. 22 and FIG. 24 to be described later, on the RAM (memory) provided in the computer and executing the computer program with the CPU (processor). The computer program defining a reinforcement learning algorithm and the Q-function or Q-value obtained by reinforcement learning according to the present embodiment may be recorded in the recording medium and distributed or may be distributed and installed to the remote monitoring target apparatuses P, U, D, M and the terminal apparatus via the network N and the communication apparatus 1.

In the embodiment described above, the life prediction simulator 24 has been used, but instead of the lifetime prediction simulator 24, a configuration using actual measured data may be used alternatively. For example, time-series data (e.g., time-series data of a current value, a voltage value, and temperature) of the energy storage device from the state sₜ to the state sₜ₊₁ may be acquired, and reinforcement learning may be performed to update the Q-function or the Q-value. In this case, the time-series data of SOC can be obtained on the basis of the time-series data of the current value, and SOH can be estimated on the basis of the obtained time-series data of SOC. On the other hand, a measured value may be used instead of the estimated value for SOH. Further, for example, the transition of the average temperature can be obtained on the basis of the time-series data of the temperature, and SOH in consideration of the transition of the average temperature can also be obtained.

Although Q-learning has been described as an example of reinforcement learning in the embodiment described above, other reinforcement learning algorithms, such as another temporal difference learning (TD learning) may be used alternatively. For example, a learning method for updating the value of the state rather than updating the value of the action, such as Q-learning, may be used. In this method, a value V(sₜ) of the current state sₜ is updated by a formula: V(sₜ)<−V(sₜ)+α·δt. Here, δt=rₜ₊₁+γ·V(sₜ₊₁)−V(sₜ), where α is a learning rate, and δt is a TD error.

In the embodiment described above, the evaluation value table 27 has been used as an example of the action evaluation function (Q-function), but it may not be practical to represent the Q-function in the table as the number of states increases. Alternatively, it is also possible to use deep reinforcement learning, which combines reinforcement learning and deep learning techniques. For example, the number of neurons in an input layer of a neural network is made equal to the number of states, and the number of neurons in an output layer is made equal to the number of choices of the action. The output layer outputs the sum of the rewards that are subsequently obtained when the action a is performed in state s. Then, the weight of the neural network may be learned such that the output of the neural network is close to the value of {rₜ₊₁+γ/maxQ(sₜ₊₁, aₜ₊₁)}, for example.

By using the learned model learned by using the learning method described above, it is possible to propose an optimum operation method for the entire system in consideration of the health of the energy storage device. This point will be specifically described below.

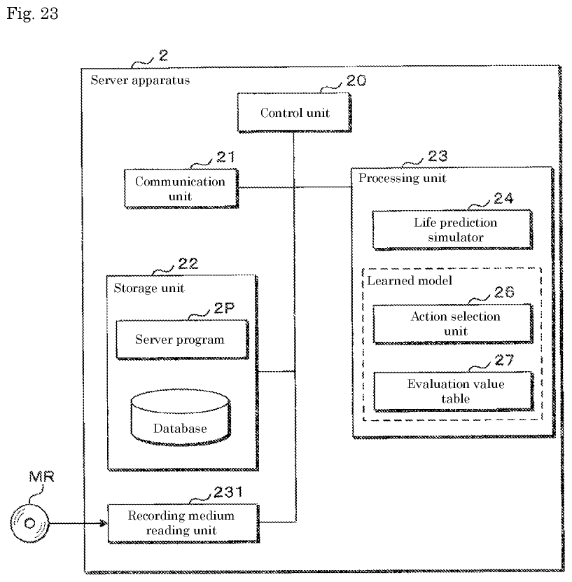

FIG. 23 is a block diagram showing an example of the configuration of the server apparatus 2 as an energy storage device evaluator. The difference from the server apparatus 2 shown in FIG. 4 is that the server apparatus 2 (processing unit 23) as the energy storage device evaluator does not include the reward calculation unit 25 and that the server apparatus 2 includes the action selection unit 26 and the evaluation value table 27 as the learned models. That is, the evaluation value table 27 has been updated, that is, learned, by the learning method described above. Note that the server apparatus 2 of FIG. 23 can also be made up of one server computer but can alternatively be made up of a plurality of server computers. Further, the reward calculation unit 25 may be provided.

FIG. 24 is a flowchart showing an example of a processing procedure for a method of the evaluation of the energy storage device by the server apparatus 2. The processing unit 23 acquires system design parameters of the energy storage device (S21). The system design parameters of the energy storage devices include the type, number, rating, and the like of the energy storage devices used in the entire system and include various parameters necessary for system design, such as the configuration or number of energy storage modules and the configuration or number of banks. The design parameters of the energy storage device are preset prior to an actual operation of the system.

The processing unit 23 acquires a state sₜ (S22) and outputs an action for the state sₜ on the basis of the learned evaluation value table 27 (S23). The processing unit 23 acquires a state stₜ₊₁ (S24) and determines whether or not an operation result of the system of the energy storage device has been obtained (S25). When the operation result is not obtained (NO at S25), the processing unit 23 sets the state sₜ₊₁ to the state sₜ (S26), and continues the processing from step S23.

When the operation result of the system of the energy storage device is obtained (YES in S25), the processing unit 23 determines whether or not there are other system design parameters (S27), and when there are other system design parameters (YES in S27), the processing unit 23 changes the system design parameters (S28) and continues the processing from step S21. When there are no other system design parameters (NO at S27), the processing unit 23 outputs the evaluation result of the energy storage device (S29) and ends the processing.

As described above, the processing unit 23 acquires the state sₜ₊₁ including SOH of the energy storage device, inputs the state sₜ₊₁ to the learning model, and acquires the obtained state sₜ₊₁ as a result of the action corresponding to the system operation including the energy storage device, the action being output by the learning model. The processing unit 23 has a function as the evaluation generation unit and generates an evaluation result of the energy storage device on the basis of the action of the energy storage device output by the learning model. The evaluation result includes, for example, the optimum operation method of the entire system including the energy storage device in consideration of the health of the energy storage device. That is, it is possible to achieve the optimum operation of the entire system in consideration of the health of the energy storage device.

The processing unit 23 can generate the evaluation result of the energy storage device in accordance with the design parameter of the energy storage device.

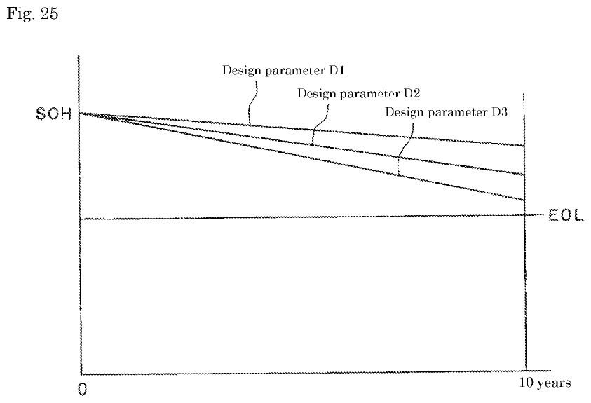

FIG. 25 is a schematic diagram showing an example of the evaluation result generated by the server apparatus 2. In the example of FIG. 25, the expected life is ten years. In FIG. 25, for convenience, the design parameters of the energy storage device are D1, D2, and D3, and the temporal change of SOH of the energy storage device when each of the design parameters is used is plotted. In the case of the system operation using the design parameter D1, SOH at the time when the expected life is reached is relatively high, and it can be seen that the design parameter gives excessive priority to the health of the energy storage device. On the other hand, in the case of the system operation using the design parameter D3, SOH at the time when the expected life is reached is relatively low, and when the operation is performed in such a manner that the power selling price is given priority, the expected life cannot be reached. Although it depends on the user's request for the system operation method, it can be evaluated that the operation using the design parameter D2 is balanced as a whole.

By generating the evaluation result of the energy storage device in accordance with the design parameter, it is possible to grasp, for example, what kind of design parameter is adopted to obtain the optimum operation method of the entire system in consideration of the health.

Although the server apparatus 2 has the processing unit 23 in the embodiment described above, the processing unit 23 may alternatively be provided on another server or a plurality of other servers. The life prediction simulator 24 may also alternatively be provided on another server or on an apparatus such as another life prediction simulator.

The embodiments are exemplary in all respects and are not restrictive. The scope of the invention is indicated by the claims and includes all modifications within the meaning and scope of the claims.

### DESCRIPTION OF REFERENCE SIGNS

2: server apparatus

2: server apparatus

20: control unit

21: communication unit

22: storage unit

23: processing unit

24: life prediction simulator

25: reward calculation unit

26: action selection unit

27: evaluation value table

1. An action generator comprising:
an action selection unit that selects an action including setting related to a state of charge (SOC) of an energy storage device on a basis of action evaluation information;
a state acquisition unit that acquires a state including a state of health (SOH) of the energy storage device when the action selected by the action selection unit is executed;
a reward acquisition unit that acquires a reward in reinforcement learning when the action selected by the action selection unit is executed;
an updating unit that updates the action evaluation information on a basis of the state acquired by the state acquisition unit and the reward acquired by the reward acquisition unit; and
an action generation unit that generates an action corresponding to the state of the energy storage device on a basis of the action evaluation information updated by the updating unit.

2. The action generator according to claim 1, wherein the setting related to SOC includes the setting of at least one of an upper limit value of SOC, a lower limit value of SOC, and an adjustment amount of SOC based on charge or discharge to/from the energy storage device.

3. The action generator according to claim 1, wherein the action includes setting of an ambient temperature of the energy storage device.

4. The action generator according to claim 1, wherein the state acquisition unit acquires information including SOH of the energy storage device output from a life prediction simulator.

5. The action generator according to claim 1, comprising:
a power generation amount information acquisition unit that acquires power generation amount information in a power generating facility to which the energy storage device is connected;
a power consumption amount information acquisition unit that acquires power consumption amount information in a power demand facility;
an SOC transition estimation unit that estimates transition of SOC of the energy storage device on a basis of the power generation amount information, the power consumption amount information, and the action selected by the action selection unit; and
an SOH estimation unit that estimates SOH of the energy storage device on a basis of the transition of SOC estimated by the SOC transition estimation unit,
wherein the state acquisition unit acquires SOH estimated by the SOH estimating unit.

6. The action generator according to claim 5, comprising
a temperature information acquisition unit that acquires ambient temperature information in the energy storage device,
wherein the SOH estimation unit estimates SOH of the energy storage device on a basis of the ambient temperature information.

7. The action generator according to claim 5, comprising
a reward calculation unit that calculates a reward in reinforcement learning on a basis of an amount of electric power sold to the power generating facility or the power demand facility,
wherein the reward acquisition unit acquires the reward calculated by the reward calculation unit.

8. The action generator according to claim 1, comprising
a reward calculation unit that calculates a reward in reinforcement learning on a basis of a power consumption amount resulting from the execution of the action,
wherein the reward acquisition unit acquires the reward calculated by the reward calculation unit.

9. The action generator according to claim 1, comprising
a reward calculation unit that calculates a reward in reinforcement learning on a basis of whether the state of the energy storage device reaches a life,
wherein the reward acquisition unit acquires the reward calculated by the reward calculation unit.

10. An energy storage device evaluator comprising:
a learned model that includes updated action evaluation information;
a state acquisition unit that acquires a state including SOH of an energy storage device; and
an evaluation generation unit that inputs the state acquired by the state acquisition unit to the learned model and generates an evaluation result of the energy storage device on a basis of an action that includes setting related to SOC of the energy storage device output by the learned model.

11. The energy storage device evaluator according to claim 10, wherein the state acquisition unit acquires information including SOH of the energy storage device output from a life prediction simulator.

12. The energy storage device evaluator according to claim 10, comprising
a parameter acquisition unit that acquires a design parameter of the energy storage device,
wherein the evaluation generation unit generates an evaluation result of the energy storage device in accordance with the design parameter acquired by the parameter acquisition unit.

13-15. (canceled)

16. An evaluation method comprising:
acquiring a state that includes a state of health (SOH) of a storage device;
inputting the acquired state into a learned model that includes updated action evaluation information; and
generating an evaluation result of the energy storage device on a basis of an action that includes setting related to a state of charge (SOC) of the energy storage device output by the learned model.
